(19) United States
(12) Patent Application Publication
(10) Pub. No.: US 2008/0272741 A1
(43) Pub. Date: Nov. 6, 2008

(54) Systems and methods for detecting power sources

(75) Inventor: Takashi Kanamori, San Jose, CA (US)

Correspondence Address: Chad R. Walsh;Fountainhead Law Group P.C., Ste. 509, 900 Lafayette St., Santa Clara, CA, 95050, US

(73) Assignee: Summit Microelectronics, inc., Sunnyvale, CA (US)

(21) Appl. No.: 11/973,798

(22) Filed: Oct. 9, 2007

Related U.S. Application Data
(60) Provisional application No. 60/927,394, filed on May 3, 2007.

(51) Int. Cl. H03K 5/15

(52) U.S. Cl. 320/137

(57) ABSTRACT

Embodiments of the present invention include techniques for detecting power sources. In one embodiment, the present invention includes a method of detecting a power source comprising coupling a power source to a portable electronic device, the power source comprising a first supply voltage and a second supply voltage, and at least a first data terminal and a second data terminal, coupling a resistor to the first data terminal a predetermined time period after the power source is coupled to the electronic device, detecting the voltage on the first data terminal and second data terminal, and generating a first signal corresponding to a first power source if the first and second data terminals have the same voltage after said predetermined time period, and generating a second signal corresponding to a second power source if the first and second data terminals have differential voltages after said predetermined time period.

### CROSS REFERENCE TO RELATED APPLICATIONS

The present application claims priority to U.S. Provisional Application No. 60/927,394, titled “Systems and Methods for Detecting Power Sources”, filed May 3, 2007.

### BACKGROUND

The present invention relates to providing power to electronic devices, and in particular, to systems and methods for detecting power sources.

Electronic devices require power in the form of voltages and currents to operate. Different electronic systems may require a wide variety of power sources with different voltages and currents to operate. For example, some systems may operate of AC voltages and currents and others may require DC voltages and currents. For AC powered systems, the voltages and currents of the power source must be in some specified range (e.g., 110V AC or 220V AC). Similarly, DC powered systems may require that the DC voltage and DC currents supplied by the power source meet certain ratings (e.g., 5 volts and 500 mA). However, the ratings of different power sources from different manufacturers may vary widely. Thus, it is desirable to determine the characteristics of a power source so that the power source may be used to provide power with an electronic system.

One area where power source detection is useful is in battery charging. Batteries have long been used as a source of power for mobile electronic devices. Batteries provide energy in the form of electric currents and voltages that allow circuits to operate. However, the amount of energy stored in a battery is limited, and batteries lose power when the electronic devices are in use. When a battery's energy supply becomes depleted, the battery's voltage will start to fall from its rated voltage, and the electronic device relying on the battery for power will no longer operate properly. Such thresholds will be different for different types of electronic devices.

Many types of batteries are designed for a single use. Such batteries are discarded after the charge is depleted. However, some batteries are designed to be rechargeable. Rechargeable batteries typically require some form of battery charging system. Typical battery charging systems transfer power from a power source, such as an AC wall plug, into the battery. The recharging process typically includes processing and conditioning voltages and currents from the power source so that the voltages and currents supplied to the battery meet the particular battery's charging specifications. For example, if the voltages or currents supplied to the battery from the power source are too large, the battery can be damaged or even explode. On the other hand, if the voltages or currents supplied to the battery from the power source are too small, the charging process can be very inefficient or altogether ineffective. Inefficient use of the battery's charging specification can lead to very long charging times, for example. Additionally, if the charging process is not carried out efficiently, the battery's cell capacity (i.e., the amount of energy the battery can hold) may not be optimized.

Accordingly, the type of power source is an important aspect of battery charging. One problem associated with charging a battery pertains to detecting the type of power source so the system can process the voltages and currents available at the power source into voltages and currents that may be used to charge a battery.

Thus, there is a need for improved systems and methods for detecting power sources.

### SUMMARY

Embodiments of the present invention improve systems and methods for detecting power sources. In one embodiment, the present invention includes electronic circuit comprising an interface controller having a power supply terminal, a ground terminal, first and second data terminals, and an output terminal coupled to a regulator, and a detection circuit coupled to at least one data terminal, wherein the first data terminal and the second data terminal are coupled to an external power source and the detection circuit senses the voltages on the first and second data terminals to determine the type of external power source.

In one embodiment, the external power source is an AC adapter and wherein the first and second data terminals are coupled together.

In one embodiment, the first and second data terminals are coupled together through a short circuit.

In one embodiment, the first and second data terminals are coupled together through a resistor.

In one embodiment, interface controller receives a power supply voltage, and in accordance therewith, generates an enable signal, wherein the enable signal selectively couples a voltage to one of said first and second data terminals.

In one embodiment, the interface controller outputs data on the output terminal to configure the regulator to charge a battery according to the power source type.

In one embodiment, the detection circuit comprises a switch coupled to the at least one data terminal, a resistor coupled between the switch and a reference voltage, and an enable terminal coupled to close the switch, wherein the enable terminal closes the switch a predetermine time period after the external power source is coupled to the interface controller, and wherein the detector circuit configures a switching regulator to charge a battery with a first current limit if the detector circuit senses that the first and second terminals are at approximately the same voltage, and the detector circuit configures a switching regulator to charge a battery with a second current limit if the detector circuit senses that the first and second terminals are at different voltages.

In one embodiment, the interface controller is a universal serial bus controller.

In another embodiment, the present invention includes a method of detecting a power source comprising coupling a power source with an electronic device, the power source comprising a first supply voltage terminal, a second supply voltage terminal less than the first supply voltage terminal, a first data terminal, and a second data terminal, coupling a resistor to the first data terminal a predetermined time period after the power source is coupled to the electronic device, detecting the voltage on the first data terminal, and generating a first signal corresponding to a first power source if the first and second data terminals have the same voltage after said predetermined time period, and generating a second signal corresponding to a second power source if the first and second data terminals have differential voltages after said predetermined time period.

In one embodiment, the resistor is coupled to a D+ data terminal, and wherein electronic device comprises a full speed USB transceiver.

In one embodiment, the resistor is coupled to a D− data terminal, and wherein electronic device comprises a low speed USB transceiver.

In one embodiment, the method further comprising configuring a switching regulator to supply a first current if the first and second data terminals have the same voltage after said predetermined time period, and configuring a switching regulator to supply a second USB current if the first and second data terminals have differential voltages after said predetermined time period.

In another embodiment, the present invention includes a method of detecting a power source comprising coupling a power source with a electronic device, the power source comprising a first supply voltage terminal, a ground terminal, a D+ data terminal, and a D− data terminal, detecting that the power source is coupled to the electronic device, closing a switch a predetermined time period after detecting the power source, and in accordance therewith, coupling the first supply voltage to one of said data terminals, sensing the voltage on the data terminals, determining the type of the power source based on the sensed voltage, and configuring a battery charger in the electronic device to charge the battery according to the type of the power source.

In another embodiment, the configuring a battery charger comprises configuring a switching regulator.

In another embodiment, the power source is an AC adapter having D+ and D− terminals short circuited together, and wherein the voltage on the data terminals is approximately the same.

In another embodiment, the power source is a USB power source having a first resistor coupled between the D+ data terminal and ground and a second resistor coupled between the D− data terminal and ground, and wherein the voltages on the D+ data terminal and D− data terminal are different.

In another embodiment, the at least one data terminal is the D+ terminal indicating that the electronic device comprises a full speed USB transceiver.

In another embodiment, the at least one data terminal is the D− terminal indicating that the electronic device comprises a low speed USB transceiver.

The following detailed description and accompanying drawings provide a better understanding of the nature and advantages of the present invention.

### BRIEF DESCRIPTION OF THE DRAWINGS

FIG. 1 illustrates an electronic device including power source detection according to one embodiment of the present invention.

FIG. 2A-C illustrates examples of power source detection according to another embodiment of the present invention.

FIG. 3A-B illustrates an example of power source detection according to another embodiment of the present invention.

FIG. 4A-B illustrates an example of power source detection according to another embodiment of the present invention.

FIG. 5 illustrates a battery charging system according to one embodiment of the present invention.

FIG. 6 illustrates an example of power source detection according to another embodiment of the present invention.

FIGS. 7A-7B illustrates the timing diagrams for the circuit of FIG. 6.

FIG. 8 illustrates a method of charging a battery according to another embodiment of the present invention.

### DISCLOSURE

Described herein are techniques for battery charging systems and methods. In the following description, for purposes of explanation, numerous examples and specific details are set forth in order to provide a thorough understanding of the present invention. It will be evident, however, to one skilled in the art that the present invention as defined by the claims may include some or all of the features in these examples alone or in combination with other features described below, and may further include obvious modifications and equivalents of the features and concepts described herein.

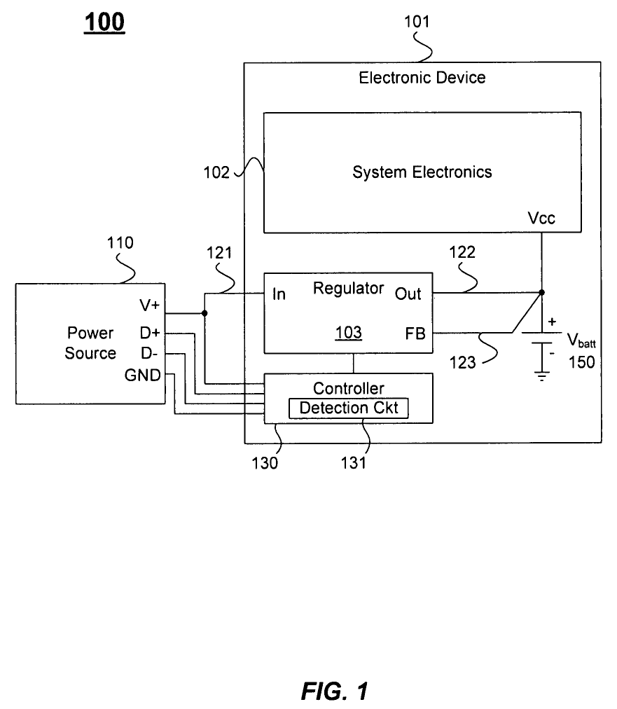

FIG. 1 illustrates an electronic device including a battery charger according to one embodiment of the present invention. Electronic device 101 includes system electronics 102, a battery 150, a regulator 103 including circuitry for charging the battery, and a controller 130 including a power source detection circuit 131. System electronics may include microprocessors, microcontrollers, wireless electronics, network electronics, or a variety of other analog or digital electrical circuits that may be powered by battery 150. The electronic device may be a mobile system, portable phone (e.g., a cellular phone), a personal digital assistant (“PDA”), a portable music or video player, or a variety of other mobile devices that may be powered by a battery. Regulator 103 may include an input terminal 121 coupled to a power source 110 and an output terminal 122 coupled to a battery 150 for charging the battery. Regulator 103 may include a feedback terminal 123 for regulating voltage or current. Example regulators are linear regulators or switching regulators, for example. Switching regulators may further include filters coupled between the regulator output and the battery, for example.

Embodiments of the present invention include a controller 130 including a power source detection circuit 131. In this example, power source 110 includes a power supply voltage terminal V+, which may provide voltage and current, a second power supply voltage terminal (here, ground-“GND”), and two data terminals (“D+” and “D−”). Controller 130 includes inputs coupled to the V+, GND, D+, and D− terminals of the power source 110. An example controller may be included in electronic device 101 as a separate integrated circuit, for example. As described in more detail below, a detection circuit 131 for detecting the power source may be included on the controller 130. Detection circuit may couple a passive network (e.g., one or more resistors) to at least one data terminal a predetermined time period after the power source is coupled to the electronic device, and detect or sense the voltages of the data terminals a predetermined time period after the power source is coupled to the electronic device to determine the type of power source. In this example, the voltages would be considered an attribute of the power source and the type of power source would be a characteristic of the power source. In one embodiment, the controller 130 generates a first signal corresponding to a first power source (e.g., an AC adapter) if the first and second data terminals have the same voltage after said predetermined time period, and the controller 130 generates a second signal corresponding to a second power source (e.g., a USB port power source—host or hub) if the first and second data terminals have differential voltages after said predetermined time period

For example, a Universal Serial Bus (“USB”) is an example of a DC power source that may be used to charge a battery. USB typically includes a power supply voltage, V+, which may be coupled to electronic device 101, for example. The voltage and current from the USB power source may be coupled through regulator 103 to power the system electronics 102, or charge the battery 150, or both. However, different power sources, such as USB, may have different power ratings. For example, some USB power sources are designed to provide 5 volts and a maximum of 500 mA. Other USB power sources are designed to provide 5 volts and a maximum of 100 MA. More generally, a power source capable of plugging into a wall power supply may transform the AC voltage and current into DC voltage and current and provide a variety of different DC voltages and currents that may be used to power device 101 or charge battery 150. One example unit is a AC to DC converter that receives AC voltages and currents and outputs a USB voltage, such as 5 volts, and a certain maximum current. The maximum current may be an attribute of the power source in this example. One particular problem with these power sources is that the current available may be different depending on the manufacturer, and if regulator 103 draws more current than the power source can supply, then the voltage of the power source will start to drop (i.e., the power source will collapse). For example, wall adapters providing a USB compatible output may provide 300 mA, while other USB compatible wall adapters may provide 1500 mA or more. It is to be understood that the AD to DC power source could be a USB compatible or another AC to DC power source. Embodiments of the present invention may be used to detect whether a power source is an AC power source or a DC power source, for example. In this example, the characteristic “AC” or “DC” corresponds to the type of power conversion employed by the power source.

In some embodiments, some power sources and interfaces for mobile terminal equipment may benefit from detecting a power source by reading the impedance between D+ and D−. In some power sources, D+ and D− may be shorted inside the power source, and the shorted node may be floating. This means that D+ and D− are shorted together or coupled together through a small impedance (e.g., sufficiently smaller than 1.5 kohm or 1.5 kohm).

In USB systems, D+ and D− are the signal lines used to implement the USB protocol. D+ and D− form a differential pair. D+ and D− lines carry binary data from an upstream port (e.g., a USB host or hub port) to downstream devices, or from downstream devices to the upstream port. If D+ and D− is a differential pair, the voltage level on one is typically greater than the other. An exception to this may be particular states that occur outside a predetermined time interval after the power source is coupled to the electronic device. For example, in a USB system, the voltages on D+ and D− are different except in an SE0 state, an SE1 state, or when a downstream device is not connected. The SE0 is a state where both D+ and D− are low, and frequently asserted to signal an end of packet, and to signal a reset. Accordingly, SE0 state does not occur near the time a USB power source is connected to the electronic device. The SE1 is a state where both D+ and D− are high. SE1 is not an intended state in USB.

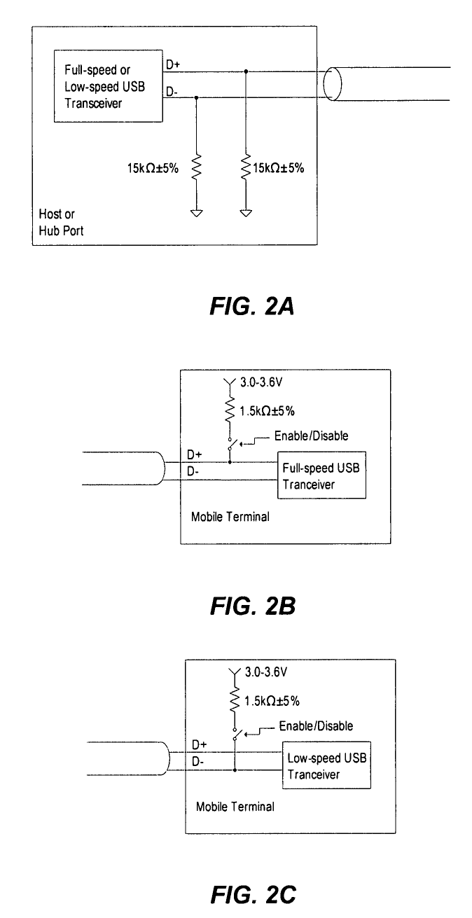

The expected difference between the voltages on D+ and D− may be used to detect the power source. In the USB example, 15kΩ±5% resistors connected to ground are typically used to terminate both D+ and D− lines at host or hub ports. This is illustrated in FIG. 2A. At the mobile device terminals, a 1.5kΩ±5% resistor connected to a voltage source between 3.0V and 3.6V may be used to pull up either D+ or D− as illustrated in FIGS. 2B and 2C. A pull up resistor coupled to the D+ line may be used to indicate a full speed USB controller device, and a pull up resistor coupled to the D− line may be used to indicate a low speed USB device, for example. This pull up resistor may reside inside the USB controller, and may be connected or disconnected by a switch activated by a specific enable signal in the controller, for example.

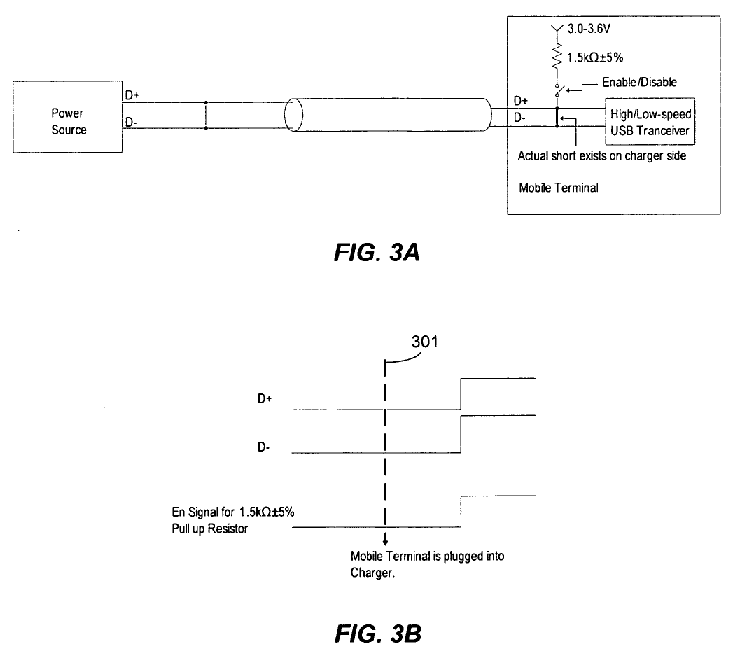

FIGS. 3A-B illustrate an example technique to detect the upstream power source. If the upstream port is an AC charger power source (e.g., an AC adapter with a DC output), D+ and D− may be shorted together, and the shorted node may be floating as in FIG. 3A. The mobile terminal may assert a specific enabling signal for the 1.5kΩ±5% pull up resistor inside the device. For example, a controller may assert a signal to couple the pull up resistor to the D+ or D− terminal after the power source is coupled to the device. If the power source has D+ and D− shorted together and floating, D+ and D− will go high when the pull up resistor is enabled a time period after the power source is coupled to the electronic device. FIG. 3B illustrates the voltages on the D+, D−, and enable lines. At time 301 the mobile device (e.g., a mobile telecommunications terminal such as a cell phone) is coupled to the power source. For example, a cable may be plugged into the power source on one side and mobile device on the other. After a time period, which may be predetermined according to an internal clock, circuit delays, or other detector settings, the enable signal may couple the pull up resistor to the D+ or D− lines. The pull up resistor will cause both D+ and D− terminals to increase in voltage. Since D+ and D− are shorted, it does not matter if the 1.5kΩ±5% is located on D+ side or on D− side. Both D+ and D− will get pulled up simultaneously.

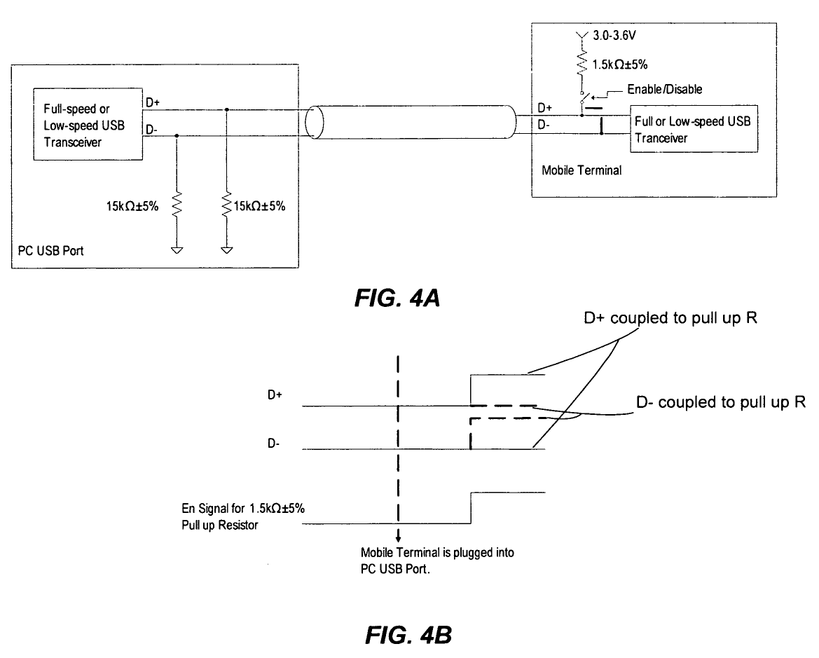

Alternatively, the upstream port may not be a power source with D+ and D— are shorted. If the connector for the upstream port is a USB connector, the upstream port is most likely to be a PC USB port. A PC USB port operates under USB protocol specified by Universal Serial Bus Specification Revision 2.0. Accordingly, the 15kΩ±5% pull down resistors are required on D+ and D− at the upstream port as in FIG. 4A. Upon connection of the cable, the mobile device asserts a specific enabling signal for the 1.5kΩ±5% pull up resistor. This may be implemented in the USB controller (sometimes referred to as the USB PHY), for example. The 1.5kΩ±5% pull up resistor is a much stronger pull up than 15kΩ±5% pull down resistor. Accordingly, with a USB port power source, only one of the two signal lines, D+or D—, will be pulled up high, while the other is pulled down by the 15kΩ±5% pull down resistor. Hence, only D+ should be pulled high for full speed device, and only D− should be pulled up high for low speed device. The dashed line in FIG. 4A between D+ and D− illustrates that the pull up resistor may be coupled to either the D+ or D− line. The dashed line is the case where the pull up resistor is coupled to D− and not D+. This non-correspondence between the first voltage, on the first data terminal, D+, and the second voltage on the second data terminal, D−, is an attribute of the power source, in this example. This is illustrated in FIG. 4B, where the dashed vertical line indicates the time where the cable is connected between the power source and mobile device, and the dashed lines on the D+ and D− terminals indicate the signal transitions if the D− cable is connected to the pull up resistor. Table 1 illustrates a truth table

TABLE 1
Truth Table, Signals vs. Upstream Power Source

Upstream Power Source

| Signals | AC Adapter | PC USB Port |
|---|---|---|
| EN for the 1.5 kΩ ± 5% | 1 | 1 |
| pull up resistor | | |
| D+ | 1 | 1/0 |
| D− | 1 | 0/1 |

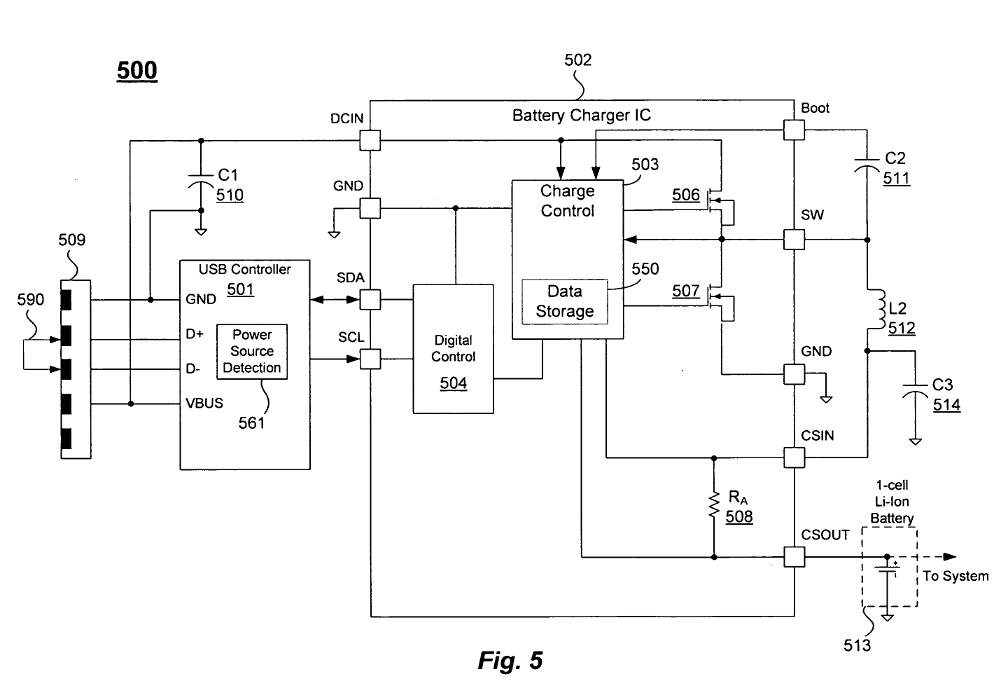

FIG. 5 illustrates a battery charging system according to one embodiment of the present invention. This example illustrates an integrated circuit that may be included on an electronic device and used to charge a battery using the techniques described above. An electronic device 500 may include a USB socket 509 for receiving a USB cable. The USB cable may include a ground connection (GND), a DC voltage (VBUS), and two data lines (D+ and D−). Socket 509, therefore, includes a ground connection, input voltage connection, and two data connections. In some applications, an AC to DC wall adapter may provide a USB compatible output including the four above mentioned outputs. Since a wall adapter may not provide data outputs, the D+ and D− terminals may be connected together (i.e., short circuited) as illustrated by 590. In other applications, a USB port power source (e.g., a USB host or hub) may provide a USB compatible output including the four above mentioned outputs. Embodiments of the invention detect the type of power source and may be used to configure a battery charger, for example.

In this example, the electronic device may include a USB controller 501 coupled to the USB socket for receiving VBUS, GND, D+, and D−. USB controller may couple data between integrated circuit 502 to a USB host or hub controller, for example. In this example, the USB controller acts as an interface circuit. The USB controller 501 may include a power source detection circuit 561 as describe above. In one embodiment the controller 501 may include an internal pull up resistor. The pull up resistor may be selectively coupled to the D+ input terminal of the controller or the D− input terminal of the controller. If a USB power source is provided to socket 509, controller 501 may detect the power and/or ground lines and generate an enable signal after a time period. The enable signal may couple an internal resistor in the controller to the D+ or D− lines as described above. If the socket 509 is coupled to an AC adapter with D+ and D− shorted together, then the voltage on both the D+ and D− terminals will increase. This state may be sensed and used to indicate that the power source is a dedicated charging power source such as an AC adapter (e.g., a USB adapter). A characteristic of the power source may correspond to a type of power conversion employed by the power source. Alternatively, if the socket 509 is coupled to an USB port with D+ and D− coupled to ground through separate pull down resistors, then the voltage on the D+ and D− terminals will be different. One of the terminals will be pulled to ground through the pull down resistor, and the other terminal will be pulled up through the pull up resistor. This state may be sensed and used to indicate that the power source is a USB port.

In this example, integrated circuit 502 includes an input terminal (e.g., a package pin DCIN) for receiving the power source voltage VBUS, with a DC capacitor 510 coupled between DCIN and ground. Integrated circuit 502 includes a charge controller 503 for implementing switching regulation and battery charging algorithms. Controller 503 may include data storage 550 (e.g., volatile or nonvolatile memory) for storing one or more values used to configure the charger, for example. Integrated circuit 502 further includes digital pins SDA and SCL for communicating information with USB controller 501 for programming and configuring the integrated circuit. For example, the USB controller may generate one or more signals that are received by charger 502 that correspond to the power source. The USB controller may signal the charger that the power source is an AC adapter, and may configure the charger to produce a first current or current sequence. Alternatively, the USB controller may signal the charger that the power source is a USB port power source, and may configure the charger to produce a second current or current sequence that uses less current than the first current or current sequence. The digital controller 504 may receive information from USB controller 501 and configure registers or other data storage elements in the integrated circuit to program the circuit to perform the desired functions, including programming charge current levels, current limits, threshold voltages, or expected power source input voltages, for example. In this example, controller 501 includes a power source detection circuit 561. Power source detection circuit 561 may detect a short circuit between the D+ and D− USB lines as illustrated by 590, which may be used in wall adapters where no data is transmitted, as described above. If a short circuit is detected, integrated circuit 502 may operate in a first charging mode by programming a plurality of registers with charging parameters corresponding to a wall adapter power source. If a short circuit is not detected (i.e., if an open circuit is detected), integrated circuit 502 may operate in a second charging mode by programming a plurality of registers with charging parameters corresponding to a USB power source. For example, in a USB power source mode, the system may be configured with charge parameters based on information communicated between a USB host or hub controller and the integrated circuit controller 504 through USB controller 501, for example.

In this example, the regulator is a switching regulator. Accordingly, integrated circuit 502 includes a first switching transistor 506 coupled between the DCIN pin and a switching output pin SW. A second switching transistor 507 may be coupled between the SW pin and a ground pin GND for establishing a ground connection. The gates of switching transistors 506 and 507 are coupled to the controller 503 for receiving switching signals, such as pulse width modulation (“PWM”), for example. The switching output pin is coupled to an inductor 512 and capacitor 514, which forms a filter. In this example, integrated circuit 502 further includes a current sense input pin CSIN coupled to the output of the filter. CSIN pin is coupled through a resistor 508 to a current sense output pin CSOUT. First and second terminals of resistor 508 are coupled to charge controller 503, and in accordance therewith, controller 503 may detect the output current of the regulator. CSOUT pin is coupled to battery 513, which in this example is a 1 cell lithium ion (Li-ion) battery, and to other system electronics of the electronic device. The output current, which is also the charge current in this example, may be set to an initial value based on the detected power source and the battery charge circuit enabled. If the battery source is an AC adapter, the output current may be set to a high current value such that the input current (i.e., the current from the adapter) is has high as 1800 mA, for example. If the battery source is a USB port with data (e.g., a USB hub or host), then the output current may be set to a lower current value such that the input current does not exceed 100 mA or 500 mA, for example. The input current may also be controlled by setting an input current limit of the charger circuit, for example. The current limit or rating may be another attribute of the power source. This attribute may correspond to a maximum current available from of the power source. The output voltage or rated voltage may be attributes of the power source. This attribute corresponds to a voltage which may be used to configure a boost or buck regulator in order to provide the most efficient charging of the battery.

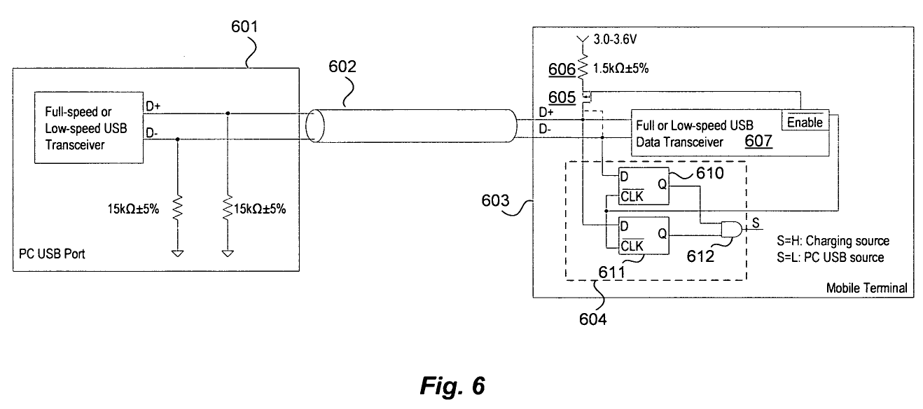

FIG. 6 illustrates an example of power source detection according to another embodiment of the invention. FIG. 6 includes a PCB USB port 601, a USB connection medium 602, and a mobile terminal 603 (i.e., a mobile or portable device). The mobile terminal 603 includes a FET switch 605, a pull up resister 606, a data transceiver 607, and a detection circuit 604. The pull up resister 606 has one terminal coupled to the drain terminal of the FET switch 605 and the other terminal coupled to receive a reference voltage. The FET has its source terminal coupled to the first data terminal D+, or alternately coupled to the second data terminal D− (shown as a dashed line). The D+ terminal and D− terminal are coupled to the data transceiver 607 in order to communicate data over the USB connection medium 602. The detection circuit 604 includes a first D flip flop 611 and a second D flip flop 610, and a AND gate 612. A first enable terminal of the data transceiver is coupled to the gate terminal of the FET switch 605 and a second enable terminal is coupled to the clock input terminal of each of the D flip flops. This may be included to account for different voltage requirements of the switch 605 and the D flip flops or may be included to delay the latching clock signal until after the voltages have settled due to the switching of the FET switch 605. The D terminal of the first D flip flop 611 is coupled to the first data terminal D+ and the D terminal of the second D flip flop 610 is coupled to the second data terminal D−. The Q output terminal of the first D flip flop is coupled to the first input terminal of the AND gate, and the Q output terminal of the second D flip flop is coupled to the second input terminal of the AND gate. The output terminal of the AND gate may be coupled to a controller (not shown) in order to configure the device.

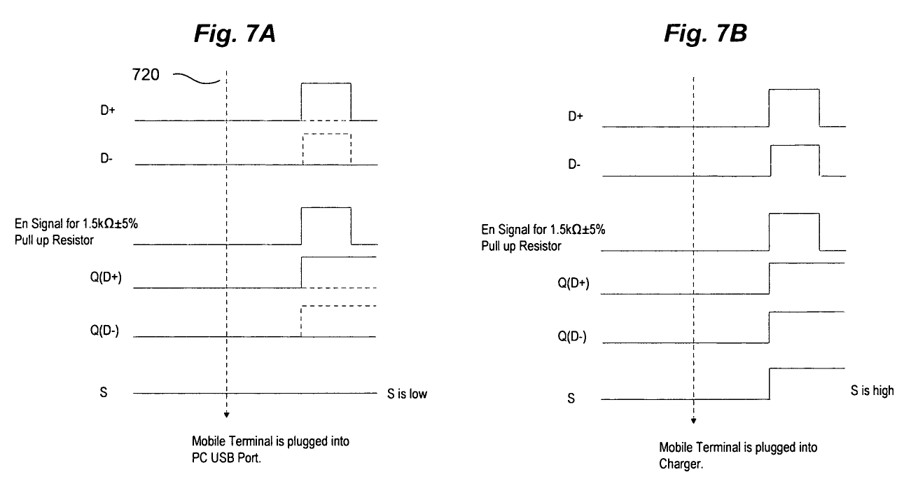

FIGS. 7A-7B illustrates the timing diagrams for the circuit of FIG. 6. In FIG. 7A, a mobile terminal is coupled to a USB hub or host at a time illustrated by vertical dashed line 720. When the USB hub or host connection is established, the D+ and D− terminals of the detection circuit are pulled down by the 15 KOhm resistors in the USB port. However, after a period of time, enable signals turn on transistor 605 and clocks the D flip flops 610 and 611. The first data terminal D+ is pulled high by switch 605. Since the D+ and D− terminals are coupled to a USB port having pull down resistors on both terminals, the D input of flip flop 611 receives a high voltage and the D input of flip flop 610 receives a low voltage. Accordingly, the Q output terminal of D flip flop 611 goes high and the Q output terminal of D flip flop 610 remains low. This causes the output “S” output of the AND gate to remain low, which indicates to the mobile terminal that the power source connected is a PC USB host. The dashed lines indicate an alternate scenario in which the pull up resistor is connected to the second data terminal D−. In this alternate scenario the second data terminal D− is pulled high by switch 605 and that makes the Q output terminal of D flip flop 610 go high and the Q output terminal of D flip flop 611 remain low. Thus, the output “S” of AND gate 612 is again low, which indicates to the mobile device that the power source connected is a PC USB host. In this example, the different in voltage on the first data terminal D+ and on the second data terminal D− is used to detect the power source type.

FIG. 7B illustrates a timing diagram for the case of an AC adapter power source connected to the mobile terminal. In this case the switch 605 is turned on by the enable signal and the short circuit between the first and second data terminals results in both D+ and D− terminals having the same voltage, which is a high voltage. The high voltage levels are received in both D flip flops, and therefore, cause both inputs of the AND gate to be high. This causes the output of the AND gate “S” to go high as well. In this example, the voltage on the first data terminal is approximately the same as the voltage on the second data terminal. It is to be understood that there may be small differences between the voltages in this case. For example, some AC adapter power sources may include small resistances which may cause the voltage at the D+ and D− terminals to differ by small amounts. However, relative to the difference between the D+ and D− terminal voltages when a USB port is connected, the voltages on the D+ and D− terminals when the AC adapter is connected are approximately the same.

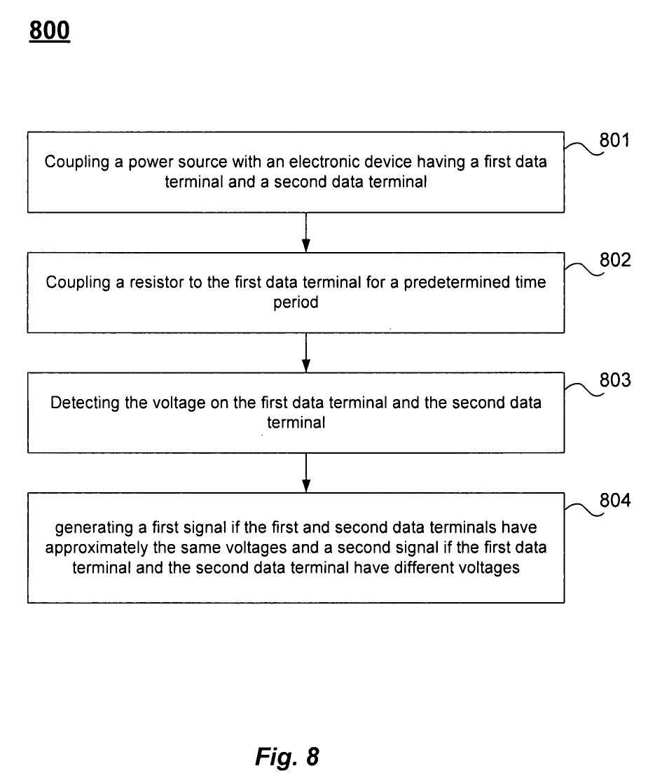

FIG. 8 illustrates a method of charging a battery according to another embodiment of the present invention. At 801, the power source is coupled with an electronic device, the power source comprising a first supply terminal, a second supply voltage terminal, a first data terminal and a second data terminal. This power source may have a USB connection or another type of connection used for differential signaling, for example. At 802, a resister is coupled to the first data terminal a predetermined time period after the source is coupled to the electronic device. At 803, the voltage on the first data terminal and the voltage on the second data terminal are detected. At 804, a first signal is generated corresponding to a first power source if the first and second data terminals have approximately the same voltages after said predetermined time period, or a second signal is generated corresponding to a second power source if the first and second data terminal have different voltages after said predetermined time period.

The above description illustrates various embodiments of the present invention along with examples of how aspects of the present invention may be implemented. The above examples and embodiments should not be deemed to be the only embodiments, and are presented to illustrate the flexibility and advantages of the present invention as defined by the following claims. For example, it is to be understood that some or all of the features, blocks, and components described above may be integrated on an integrated circuit. Based on the above disclosure and the following claims, other arrangements, embodiments, implementations and equivalents will be evident to those skilled in the art and may be employed without departing from the spirit and scope of the invention as defined by the claims. The terms and expressions that have been employed here are used to describe the various embodiments and examples. These terms and expressions are not to be construed as excluding equivalents of the features shown and described, or portions thereof, it being recognized that various modifications are possible within the scope of the appended claims.

What is claimed is:

1. A electronic circuit comprising:
an interface controller having a power supply terminal, a ground terminal, first and second data terminals, and an output terminal coupled to a regulator; and
a detection circuit coupled to at least one data terminal;
wherein the first data terminal and the second data terminal are coupled to an external power source and the detection circuit senses the voltages on the first and second data terminals to determine the type of external power source.

2. The electronic circuit of claim 1 wherein the external power source is an AC adapter and wherein the first and second data terminals are coupled together.

3. The electronic circuit of claim 2 wherein the first and second data terminals are coupled together through a short circuit.

4. The electronic circuit of claim 2 wherein the first and second data terminals are coupled together through a resistor.

5. The electronic circuit of claim 1 wherein interface controller receives a power supply voltage, and in accordance therewith, generates an enable signal, wherein the enable signal selectively couples a voltage to one of said first and second data terminals.

6. The electronic circuit of claim 1 wherein the interface controller outputs data on the output terminal to configure the regulator to charge a battery according to the power source type.

7. The electronic circuit of claim 1 wherein the detection circuit comprises:
a switch coupled to the at least one data terminal;
a resistor coupled between the switch and a reference voltage; and
an enable terminal coupled to close the switch,
wherein the enable terminal closes the switch a predetermine time period after the external power source is coupled to the interface controller, and
wherein the detector circuit configures a switching regulator to charge a battery with a first current limit if the detector circuit senses that the first and second terminals are at approximately the same voltage, and the detector circuit configures a switching regulator to charge a battery with a second current limit if the detector circuit senses that the first and second terminals are at different voltages.

8. The electronic circuit of claim 1 wherein the interface controller is a universal serial bus controller.

9. A method of detecting a power source comprising:
coupling a power source with an electronic device, the power source comprising a first supply voltage terminal, a second supply voltage terminal less than the first supply voltage terminal, a first data terminal, and a second data terminal;
coupling a resistor to the first data terminal a predetermined time period after the power source is coupled to the electronic device;
detecting the voltage on the first data terminal; and
generating a first signal corresponding to a first power source if the first and second data terminals have the same voltage after said predetermined time period, and generating a second signal corresponding to a second power source if the first and second data terminals have differential voltages after said predetermined time period.

10. The method of claim 9 wherein the resistor is coupled to a D+ data terminal, and wherein electronic device comprises a full speed USB transceiver.

11. The method of claim 9 wherein the resistor is coupled to a D− data terminal, and wherein electronic device comprises a low speed USB transceiver.

12. The method of claim 9 further comprising configuring a switching regulator to supply a first current if the first and second data terminals have the same voltage after said predetermined time period, and configuring a switching regulator to supply a second USB current if the first and second data terminals have differential voltages after said predetermined time period.

13. A method of detecting a power source comprising:
coupling a power source with a electronic device, the power source comprising a first supply voltage terminal, a ground terminal, a D+ data terminal, and a D− data terminal;
detecting that the power source is coupled to the electronic device;
closing a switch a predetermined time period after detecting the power source, and in accordance therewith, coupling the first supply voltage to one of said data terminals;
sensing the voltage on the data terminals;
determining the type of the power source based on the sensed voltage; and
configuring a battery charger in the electronic device to charge the battery according to the type of the power source.

14. The method of claim 13 wherein configuring a battery charger comprises configuring a switching regulator.

15. The method of claim 13 wherein the power source is an AC adapter having D+ and D− terminals short circuited together, and wherein the voltage on the data terminals is approximately the same.

16. The method of claim 13 wherein the power source is a USB power source having a first resistor coupled between the D+ data terminal and ground and a second resistor coupled between the D− data terminal and ground, and wherein the voltages on the D+ data terminal and D− data terminal are different.

17. The method of claim 13 wherein the at least one data terminal is the D+ terminal indicating that the electronic device comprises a full speed USB transceiver.

18. The method of claim 13 wherein the at least one data terminal is the D− terminal indicating that the electronic device comprises a low speed USB transceiver.
